(19) United States
(12) Patent Application Publication
(10) Pub. No.: US 2022/0102566 A1
(43) Pub. Date: Mar. 31, 2022

(54) COLOR-CODED PATTERNS FOR EPITAXIAL LIFT-OFF (ELO) FILMS BACKGROUND

(71) Applicant: Utica Leaseco, LLC, Rochester Hills, MI (US)

(72) Inventor: Andrew J. RITENOUR, San Jose, CA (US)

(21) Appl. No.: 17/483,271

(22) Filed: Sep. 23, 2021

Related U.S. Application Data
(60) Provisional application No. 63/083,250, filed on Sep. 25, 2020.

(51) Int. Cl. H01L 31/05; H01L 31/0224; H01L 31/056; H01L 31/0216; H01L 31/18

(52) U.S. Cl. CPC H01L 31/0512; H01L 31/022441; H01L 31/186; H01L 31/02168; H01L 31/056

(57) ABSTRACT

The present disclosure provides a photovoltaic device formed according to a color code scheme and methods of manufacturing thereof. In an example, the photovoltaic device may include one or more photovoltaic cells formed according to one or more applications of the photovoltaic cells. The photovoltaic device may also include a rear contact layer formed on a rear surface of the one or more photovoltaic cells, the rear contact layer including one or both of a composition or a thickness configured to produce a unique color code in the color code scheme that is visible in areas of the photovoltaic device outside of areas covered by the photovoltaic cells and corresponding to the particular product configuration of the photovoltaic device. The photovoltaic device may also include a back reflector formed on a rear surface of the rear contact layer.

### CROSS-REFERENCE TO RELATED APPLICATION(S)

This application claims the benefit of U.S. Provisional Application No. 63/083,250, entitled “Color-Coded Patterns for Epitaxial Lift-Off (ELO) Films Background” and filed on Sep. 25, 2020, which is expressly incorporated by reference herein in its entirety.

### BACKGROUND

### Technical Field

The present disclosure relates generally to photovoltaic devices, such as solar cells, and methods of manufacturing such photovoltaic devices.

### Introduction

Photovoltaic devices, such as solar cells, solar modules, or solar panels, harness energy from the sun to generate a voltage, thereby converting light energy to electric energy. The photovoltaic devices may be used in a range of different applications, including, but not limited to, aerial or space vehicles, residential homes, or consumer products. Despite the use of different connections, materials, components, or assembly during manufacturing to meet specific application needs, different types of products having photovoltaic devices may visibly appear to be substantially the same. This may cause confusion when handling the products in a factory that can result in unnecessary manufacturing delays to determine appropriate subsequent processing, which tends to increase manufacturing costs.

Accordingly, there exists a need for further improvements to photovoltaic devices and the manufacturing thereof that may make it easier to identify different products by simple techniques such as visual inspections.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

In an aspect, a photovoltaic device that produces a unique color code in a color code scheme to identify a particular product configuration of the photovoltaic device is provided. The photovoltaic device may include one or more photovoltaic cells having a top surface on which light is to be incident. The photovoltaic device may include a rear contact layer formed on a rear surface of the one or more photovoltaic cells, the rear contact layer including one or both of a composition or a thickness configured to produce a unique color code in a color code scheme visible to a user in areas of the photovoltaic device outside of areas covered by the one or more photovoltaic cells and corresponding to a particular product configuration of the photovoltaic device. The photovoltaic device may include a back reflector formed on a rear surface of the rear contact layer.

In another aspect, a method of forming a photovoltaic device that produces a unique color code in a color code scheme to identify a particular product configuration of the photovoltaic device is provided. The method may include forming one or more photovoltaic cells. The method may include forming a rear contact layer on a rear surface of the one or more photovoltaic cells. The method may include forming a reflector on a rear surface of the contact layer, wherein the one or more photovoltaic cells have a top surface on which light is to be incident, and wherein the rear contact layer includes one or both of a composition or a thickness configured to produce the unique color code in the color code scheme visible to a user in areas of the photovoltaic device outside of areas covered by the one or more photovoltaic cells and corresponding to the particular product configuration of the photovoltaic device.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIGS. 1A and 1B illustrate a first example of a photovoltaic device, according to aspects of the present disclosure;

FIGS. 2A and 2B illustrate a second example of a photovoltaic device, according to aspects of the present disclosure;

FIG. 3 illustrates a flowchart of an example method of forming one or more photovoltaic devices, according to aspects of the present disclosure; and

FIG. 4 illustrates an example of a pre-processing inspection system, according to aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Typically, different photovoltaic devices are manufactured using the same manufacturing flow, meaning the same manufacturing process may be used with little to no retooling of machinery to manufacture the different photovoltaic devices. Different photovoltaic devices may refer to different product configurations in which, for example, different types of solar cells may be used, different processes may be used, different numbers of solar cells may be used, different arrangements of the solar cells may be used, or different binning of the solar cells may be used. However, during the manufacturing process and/or after the manufacturing process, the different photovoltaic devices may visually appear to be the same or very similar devices. In other words, it may be difficult for someone in the manufacturing line to determine a particular product configuration of a photovoltaic device by a simple visual inspection. Typically, the use of one or more identification methods or techniques for visual identification of the photovoltaic devices has included reconfiguration of front metal patterns. However, these methods or techniques may result in additional costs due to retooling the manufacturing process and/or may result in films being processed with an incorrect front metal pattern. Moreover, changes to an anti-reflective coating (ARC) or to the front metal on a top or front side of the photovoltaic device to produce some form of visual identification may instead result in a loss of performance of the photovoltaic device. As such, other methods or techniques are needed to help identify different types of photovoltaic device products.

Aspects of the present application use color-coded patterns (e.g., colors or color codes that are part of a color code scheme) for epitaxial lift-off (ELO) films in order to distinguish or identify between different photovoltaic devices that would otherwise be visually similar. In this regard, the photovoltaic device may be made from epitaxially grown photovoltaic structures (e.g., photovoltaic or solar cells) that are separated from a growth substrate by removing a sacrificial layer through an ELO process. The photovoltaic structures removed from the growth structure may be referred to as ELO films and may include photovoltaic cells and/or other layers. In some instances, these photovoltaic cells may have a common contact layer and reflector at the bottom (e.g., back or rear contact layer, back or rear metal reflector), and the photovoltaic cells may be isolated by an etching process that exposes the rear contact layer between the photovoltaic cells before an ARC coating is deposited over both the photovoltaic cells and the exposed portion of the rear contact layer. In an example, the finished photovoltaic device is such that there are areas around the photovoltaic cells (e.g., streets or edges in the outer perimeter of the cells) that contain some amount of the rear contact layer exposed by the etching process. By adjusting the composition and/or thickness of the rear contact layer during a metal organic chemical vapor deposition (MOCVD) epitaxial growth operation, an aesthetic effect, including color, iridescence, transparency, etc., produced by the exposed portion may be controlled such that a unique visual effect can be achieved and can be used to identify other aspects of the photovoltaic device. For example, by changing the aesthetic or visual effect, it is then possible during the manufacturing flow to enable a color-coding scheme associated with the effect to assist in flow identification without any changes in tooling other than the epitaxial growth recipe. Moreover, changing the composition and/or the thickness of the rear contact layer produces minimal effects on the overall performance of the photovoltaic device, so adjustments to this layer to produce a desired visual identifier in the form of a unique color code for a particular product configuration should not have much of an effect on the photovoltaic device.

Turning now to the figures, examples of photovoltaic devices and methods of manufacturing the photovoltaic devices are described herein. It is to be understood that layers and components in the figures may not be drawn to scale and are instead drawn for illustrative purposes.

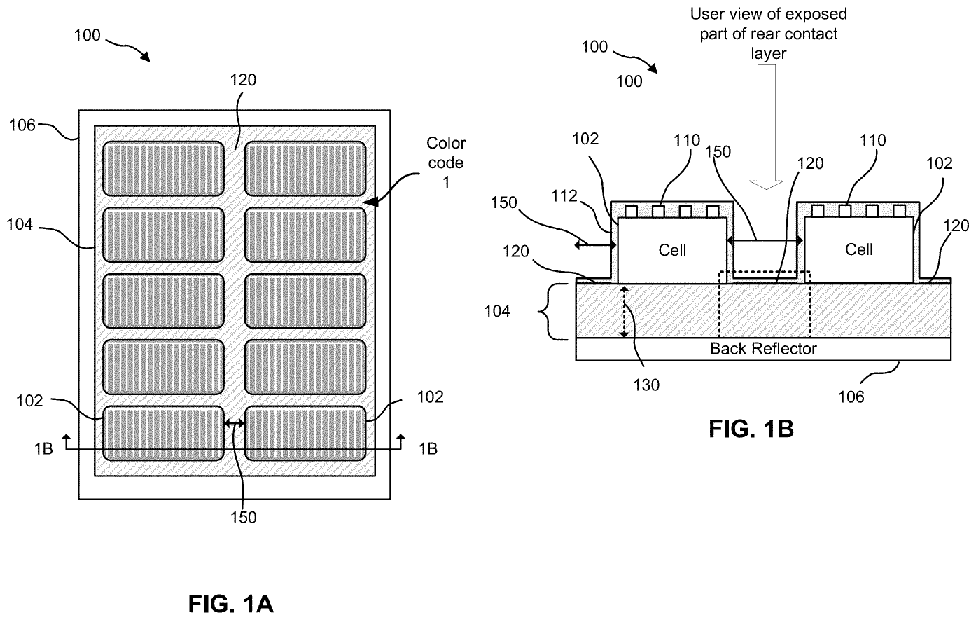

Referring to FIGS. 1A and 1B, different views of a photovoltaic device 100 having a first color code (e.g., color code 1) are depicted. FIG. 1A illustrates a top-down view of the photovoltaic device 100, and FIG. 1B illustrates a cross-sectional view of the photovoltaic device 100 along the lines 1B-1B. In an aspect, the photovoltaic device 100 may be formed during a manufacturing process and include a plurality of photovoltaic cells 102 that correspond to a first application (e.g., one of space vehicle, residential home, or consumer product). Moreover, the photovoltaic device 100 and the photovoltaic cells 102 may be configured for a particular product for the first application. For example, the particular product may use certain types of photovoltaic cells 102 (e.g., single junction cells, dual junction cells, or triple junction cells), the photovoltaic cells 102 may be made using a certain process for that particular product, the number, arrangement, and/or binning of the photovoltaic cells 102 may be specifically configured for that particular product. There may be different products for different applications, and each of the products needs to be easily identified so that they are not confused during manufacturing. For example, performing a pre-processing visual inspection may be helpful in determining whether the correct batch of intermediate products is being lined up for the next processing step.

Returning to FIG. 1B, a gap 150 (or area) may be formed between each of the photovoltaic cells 102 in order to isolate one from another and/or around one or more edges of the photovoltaic device 100. That is, the gap 150 may be formed around or outside of where the photovoltaic cells 102 are placed in the photovoltaic device 100. In an example, the photovoltaic cells 102 may be high performance photovoltaic cells, such as gallium arsenide (GaAs) photovoltaic cells. The photovoltaic cells 102 may include a plurality of layers including, but not limited to, one or more semiconductor layers, an emitter layer, an absorber layer, an intermediate layer, a window layer, a top contact layer, or any other layer used for a photovoltaic cell.

In an aspect, one or more of the layers of the photovoltaic cells 102 may include compound semiconductor materials (e.g., non-silicon based materials) such as group III-V semiconductor materials, although other types of compound semiconductor materials may also be used (e.g., group II-IV semiconductor materials). The group III-V semiconductor material may include one or more group III semiconductor materials and one or more group V semiconductor materials (e.g., one group III semiconductor material and one group V semiconductor material, multiple group III semiconductor materials and one group V semiconductor material, one group III semiconductor material and multiple group V semiconductor materials, or multiple group III semiconductor materials and multiple group V semiconductor materials).

The layers having the group III-V semiconductor materials may be formed through epitaxial growth. In an example, the layers may contain a combination of two or more of gallium (Ga), arsenic (As), aluminum (Al), indium (In), or phosphorus (P) (e.g., GaAs, AlGaAs, InGaP, AlInGaP, InGaAs, AlInGaAs, InGaAsP, or AlInP). In some examples, the compound semiconductor materials of the photovoltaic cells 102 may include p-type (or p-doped), n-type (or n-doped) semiconductor materials, and/or undoped or lightly doped semiconductor materials. During manufacturing, one or more of the layers of the photovoltaic cells 102 may be formed through epitaxial growth, including the layers having the compound semiconductor materials.

In an aspect, the photovoltaic device 100 may include a rear contact layer 104 and a back reflector 106. In an example, the rear contact layer 104 may be positioned between the photovoltaic cells 102 and the back reflector 106. The rear contact layer 104 may also be referred to as a back or bottom contact layer 104. The rear contact layer 104 may be a p-type contact layer, for example. The rear contact layer 104 may be formed during manufacturing of the photovoltaic cells 102, as described herein, on the back sides of the photovoltaic cells 102. The rear contact layer 104 may be formed of group III-V semiconductor materials, as described herein.

The back reflector 106 (also referred to as a back metal reflector) may include one or more materials configured to reflect traversing light back into the photovoltaic cells 102 to improve overall efficiency. Examples of the materials may include gold (Au), silver (Ag), copper (Cu), aluminum (Al), or other reflective metals, derivatives thereof, and/or combinations thereof. In some examples, the back reflector 106 may be deposited on a back surface of the rear-contact layer 104 during manufacturing. However, in other examples, one or more additional layers (e.g., dielectric layer) may be positioned between the rear contact layer 104 and the back reflector 106.

The photovoltaic device 100 may also include one or more front contacts 110 (or contact fingers) configured to conduct voltage and current, produced through a photovoltaic process, to external circuitry (not shown) corresponding to semiconductor layers (e.g., n-type or p-type semiconductor layers) of the photovoltaic cells 102. The one or more front contacts 110 may be located on a front or top side of the photovoltaic cells 102. In an aspect, the one or more front contacts 110 may include a metallic stack (e.g., metal contact stack) containing multiple layers of varying compositions of materials.

In an aspect, the photovoltaic device 100 may include an anti-reflective coating (ARC) layer 112 including one or more materials that are configured to allow light to pass through a front surface of the ARC layer 112 and prevent light reflection from the ARC layer 112. The ARC layer 112 may be disposed on different surfaces of the photovoltaic device 100, including surfaces of the photovoltaic cells 102, a front surface 120 of the rear contact layer 104, and surfaces of the one or more front contacts 110. In some examples, the ARC layer 112 may contain magnesium fluoride (MgF2), zinc sulfide (ZnS), titanium oxide (TiO), titanium dioxide (TiO2), niobium oxide (NbO, NbO2, or Nb2O5), silicon nitride (Si3N4), silicon oxynitride (SiOxNy), silicon oxide (SiO), silicon dioxide (SiO2), derivatives thereof, or combination thereof. In some examples, the ARC layer 112 may be made of one or more layers of material.

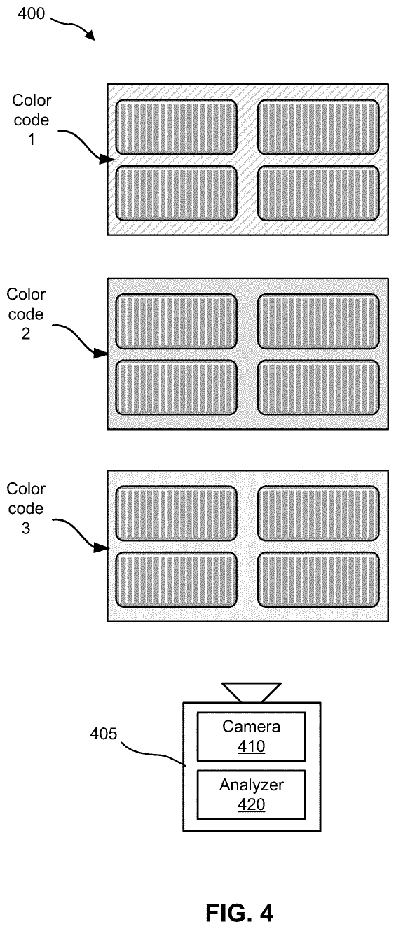

As shown in FIG. 1B, a user (e.g., an operator or an automated inspection system as shown in FIG. 4) may identify the unique color code (e.g., color code 1) that corresponds to the product of the photovoltaic device 100 by the visual effects produced on the portion of the rear contact layer 104 that is exposed in between or around the photovoltaic cells 102.

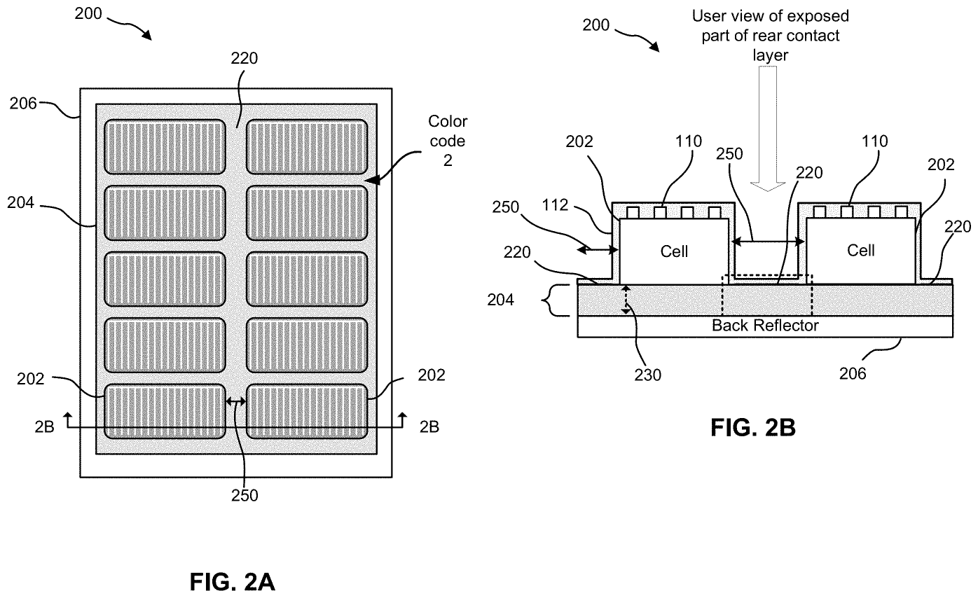

Referring to FIGS. 2A and 2B, different views of a second photovoltaic device 200 having a second color code (e.g., color code 2) are depicted. FIG. 2A illustrates a top-down view of the second photovoltaic device 200, and FIG. 2B illustrates a cross-sectional view of the second photovoltaic device 200 along the lines 2B-2B.

In an aspect, the photovoltaic device 200 may be formed during a manufacturing process and include a plurality of photovoltaic cells 202 that correspond to the first application described above in connection with the photovoltaic cells 102 or to a second application (e.g., one of space vehicle, residential home, or consumer product) different from the first application for the photovoltaic cells 102. In either case, the photovoltaic device 200 and the photovoltaic cells 202 may be configured for a particular product that is different from the product associated with the photovoltaic device 100 and the photovoltaic cells 102. A gap or area 250 may be formed between each of the photovoltaic cells 202 in order to isolate one from another. In an example, the photovoltaic cells 202 may be formed using the above-described materials of the photovoltaic cells 102.

In an aspect, the photovoltaic device 200 may include a rear contact layer 204 and a back reflector 206. In an example, the rear contact layer 204 and the back reflector 206 may be positioned and formed of materials as described herein for the rear contact layer 104 and the back reflector 106, respectively.

The photovoltaic device 200 may also include the one or more front contacts 110 deposited on the photovoltaic cells 202 and the ARC layer 112 deposited on different surfaces of the photovoltaic device 200, including surfaces of the photovoltaic cells 202, a front surface 220 of the rear contact layer 204, and surfaces of the one or more front contacts 110.

As shown in FIG. 2B, a user (e.g., an operator or an automated inspection system as shown in FIG. 4) may identify the unique color code (e.g., color code 2) that corresponds to the product of the photovoltaic device 200 by the visual effects produced on the portion of the rear contact layer 204 that is exposed in between or around the photovoltaic cells 202.

### Color-Coding Scheme

Referring back to FIG. 1B, in an aspect, the surface 120 of the rear contact layer 104 may be exposed during an isolation etching operation to generate the gaps 150 between the photovoltaic cells 102 and/or spacing at an edge of the photovoltaic device 100. The isolation etching operation may then be followed by a process by which the ARC layer 112 is deposited or formed. By adjusting the composition and/or thickness of the rear contact layer 104 during a MOCVD epitaxial growth process (and later exposed during the isolation etching operation), various aesthetic characteristics, including color, iridescence, or transparency, produced by light incident on the surface 120 may be controlled for visible identification of the particular product configuration of the photovoltaic device 100. In other words, visible characteristics for device identification may be configured into the structure of the photovoltaic device during a manufacturing flow with little to no need for retooling the manufacturing equipment. Instead, the color-coding manufacturing operations rely on changes to a thickness and/or a composition of materials of the rear contact layer 104 for product identification. The product identification need not only identify the application for which the product is to be used but the particular configurations of the product as there may be multiple product configurations even for the same application.

As noted above, the color, also referred to as the color code, that is visible to a user from the gap 150 (or area) and used to identify the type of product configuration of the photovoltaic device 100 may be determined based on the thickness and/or the composition of the rear contact layer 104, which is exposed to the user in the gap 150. For example, a greater thickness may produce one color or color code in the color code scheme, while a smaller thickness may produce a different color or color code in the color code scheme, each of which is configured according to a corresponding product configuration of the photovoltaic device 100. Similarly, one composition (e.g., semiconductor material, molar composition, and/or doping) may produce one color or color code in the color code scheme, while a different composition may produce a different color or color code in the color code scheme, each of which is configured according to a corresponding product configuration of the photovoltaic device 100. Generally changing the thickness and/or the composition of the rear contact layer 104 need not have a significant impact on the functionality of the rear contact layer 104.

Prior to manufacturing of the photovoltaic device 100 a thickness of the rear contact layer 104 may be selected based on a particular product or product configuration of the photovoltaic device 100. For example, different thickness may be used such that different visible colors (e.g., different color codes from a gamut in a color code scheme) are produced for different products or product configurations, where the different products or product configurations may be used for the same application or for different applications.

During manufacturing, the rear contact layer 104 may be epitaxially grown to a particular thickness that corresponds to the desired color code. The thickness of the rear contact layer 104 may affect reflectivity and/or absorption of visible wavelengths resulting in a change in visible coloring characteristics. For example, a thickness of the rear contact layer 104 may be selected in which a first color code may correspond to a thickness 130 of the rear contact layer 104. As shown by FIGS. 1A and 1B, the first color code (e.g., color code 1) may be visibly exposed through an isolation etching operation.

However, in other examples, such as in the example in FIGS. 2A and 2B that use the rear contact layer 204, a second color code (e.g., color code 2) may correspond to a second thickness 230 of the rear contact layer 204 As shown, the second thickness 230 of the rear contact layer 204 is smaller than then first thickness 130 of the rear contact layer 104. Other examples are also possible in which the second thickness 230 of the rear contact layer 204 may be greater than that of the first thickness 130.

The different color codes in the color scheme may include, for example, reds, pinks, purples, and blues, where smaller thicknesses of the rear contact layer may correspond to blue and purple colors (e.g., colors with smaller visible wavelengths) and larger thicknesses of the rear contact layer may correspond to red and pink colors (e.g., colors with larger visible wavelengths). For example, a first color code (e.g., color code 1) produced by a visual inspection of the rear contact layer 104 having the thickness 130 may be a red color code that identifies the photovoltaic device 100 as being associated with one product, while a second color code (e.g., color code 2) produced by a visual inspection of the rear contact layer 204 having the thickness 230 may be a purple color that identifies the photovoltaic device 200 as being associated with another product. In this example, two different products may be visually identified by using two different thicknesses for the rear contact layer.

In another example, a first color code produced by a visual inspection of the rear contact layer 104 made with a first composition may identify the photovoltaic device 100 as being associated with one product, while a second color code produced by a visual inspection of the rear contact layer 104 made with a second composition may identify the photovoltaic device 100 as being associated with another product. In this example, two different products may be visually identified by using two different compositions to make the rear contact layer.

In yet another example, a first color code produced by a visual inspection of the rear contact layer 104 having the thickness 130 and made with a first composition may identify the photovoltaic device 100 as being associated with one product, while a second color code produced by a visual inspection of the rear contact layer 204 having the thickness 230 and made with a second composition may identify the photovoltaic device 200 as being associated with another product. In this example, two different products may be visually identified by using two different combinations of thickness and composition to make the rear contact layer.

### Manufacturing

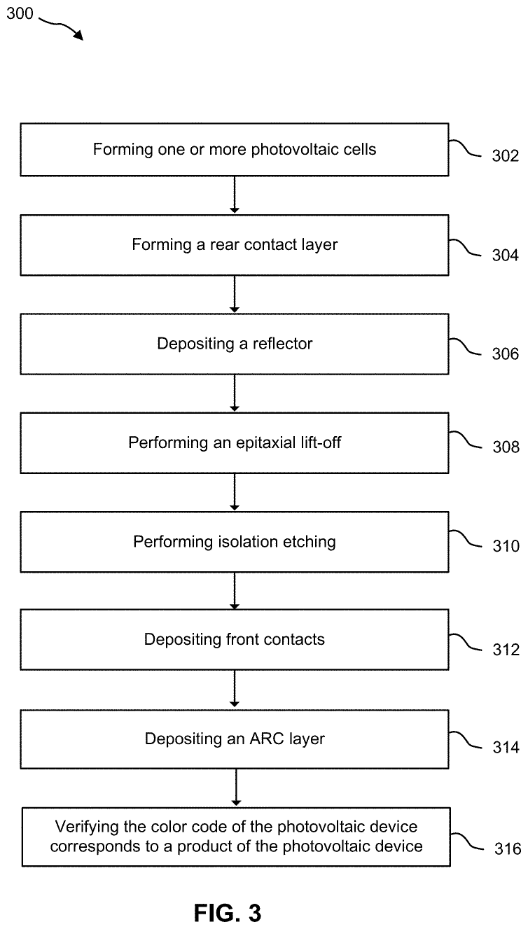

Referring to FIG. 3, an example method 300 of manufacturing a photovoltaic device (e.g., photovoltaic device 100 or photovoltaic device 200) is depicted. The below examples of the method 300 will be based on forming the photovoltaic device 100, but it is to be understood that similar approaches may be used for the type of photovoltaic devices described in this disclosure. At 302, the method 300 may include forming one or more photovoltaic cells 102 on a substrate or wafer (e.g., a growth wafer). For example, one or more semiconductor layers (e.g., group III-IV semiconductor layers) may be formed to build the structure of the photovoltaic cells 102 by epitaxial growth on the substrate. Further, additional layers may be formed and/or deposited on the substrate and/or the one or more semiconductor layers as necessary for manufacturing the photovoltaic cells 102.

At 304, the method 300 may also include forming a rear contact layer on a back surface of the one or more semiconductor layers. For example, the rear contact layer 104 may be formed on the back surface of the one or more semiconductor layers that form the photovoltaic cells 102. In an example, the rear contact layer 104 may be formed by epitaxial growth on the one or more semiconductor layers. Further, a composition and/or a thickness of the rear contact layer 104 may be determined based on an application of the photovoltaic device 100. The determination of the composition and/or thickness of the rear contact layer 104 may control aesthetic characteristics of the unique color code of the photovoltaic device 100 which corresponds to the application/product of the photovoltaic device 100, as disclosed herein.

At 306, the method 300 may also include depositing a back reflector on a back surface of the rear contact layer. For example, the back reflector 106 may be deposited on the back surface of the rear contact layer 104.

At 308, the method 300 may also include performing an epitaxial lift-off (ELO) operation to separate the substrate from the one or more semiconductor layers. For example, a sacrificial layer may be formed between the one or more semiconductor layers and the substrate, and the ELO operation may include an etching process performed to remove the sacrificial layer, thereby separating the one or more semiconductor layers from the substrate. In some examples, the rear contact layer and/or the back reflector may be formed after the separation of the photovoltaic cells 102 from the substrate.

At 310, the method 300 may also include performing isolation etching. For example, an etching process may be performed to form the gaps 150 between the photovoltaic cells 102 and the edges of the photovoltaic device 100. Further, the isolation etching may expose the surface of the rear contact layer 104 such that the surface 120 is visibly exposed such that the unique color code produced by the rear contact layer 104 may be visible to a user.

At 312, the method 300 may also include depositing front contacts on the photovoltaic cells. For example, the front contacts 110 may be deposited on the photovoltaic cells 102.

At 314, the method 300 may include depositing an ARC layer on the photovoltaic device. For example, the ARC layer 112 may be deposited on the surface (e.g., color code surface 120) of the rear contact layer 104, and one or more surfaces of the photovoltaic cells 102 and the front contacts 110.

At 316, the method 300 may include verifying a color code of the photovoltaic device corresponds to an application/product of the photovoltaic device. For example, a verification camera may be used to verify that the unique color code produced by the photovoltaic device 100 corresponds to the correct application/product of the photovoltaic device 100.

Referring to FIG. 4, the diagram 400 shows three different photovoltaic devices, one having a first color code (e.g., color code 1), another one having a second color code (e.g., color code 2), and yet another one having a third color code (e.g., color code 3). A pre-processing inspection system 405 (e.g., an automated system) may be used to inspect the unique color codes of the photovoltaic cells to determine the corresponding product and whether it is the proper product for the next manufacturing or processing step. The pre-processing inspection system 405 may include a camera 410 that is used to capture the unique color or color code of each photovoltaic device and an analyzer 420 that determines whether the color or color code of the photovoltaic device is the appropriate color for the manufacturing flow. The pre-processing inspection system 405 may therefore be configured to provide an indication that the photovoltaic device is appropriate for further processing or that the photovoltaic device is not appropriate for further processing and correction measures need to be taken.

The pre-processing inspection system 405 may be used to verify or ensure the color code of a particular photovoltaic cell as described above in 315 of the method 300.

It is understood that the specific order or hierarchy of blocks in the processes/flowcharts disclosed is an illustration of exemplary approaches. Based upon different implementations, it is understood that the specific order or hierarchy of blocks in the processes/flowcharts may be rearranged. Further, some blocks may be combined or omitted. The accompanying method claims present elements of the various blocks in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more.

Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

What is claimed is:

1. A photovoltaic device, comprising:
one or more photovoltaic cells having a top surface on which light is to be incident;
a rear contact layer formed on a rear surface of the one or more photovoltaic cells, the rear contact layer including one or both of a composition or a thickness configured to produce a unique color code in a color code scheme that is visible in areas of the photovoltaic device outside of areas covered by the one or more photovoltaic cells and corresponding to a particular product configuration of the photovoltaic device; and
a back reflector formed on a rear surface of the rear contact layer.

2. The photovoltaic device of claim 1, wherein the composition of the rear contact layer includes a particular composition of compound semiconductor materials to produce the unique color code.

3. The photovoltaic device of claim 2, wherein the compound semiconductor materials include group III-V semiconductor materials.

4. The photovoltaic device of claim 1, wherein the rear contact layer is formed through epitaxial growth on the rear surface of the one or more photovoltaic cells to a particular thickness configured to produce the unique color code in the color code scheme corresponding to the particular product configuration of the photovoltaic device.

5. The photovoltaic device of claim 1, wherein a top surface of the rear contact layer is exposed via an isolation etching operation that forms the areas outside of the areas covered by the one or more photovoltaic cells to make the unique color code produced by the rear contact layer that is visible.

6. The photovoltaic device of claim 1, wherein a first thickness used for the rear contact layer corresponds to a first color code of the color code scheme and a second and different thickness used for the rear contact layer corresponds to a second and different color code of the color code scheme.

7. The photovoltaic device of claim 1, wherein a first composition used for the rear contact layer corresponds to a first color code of the color code scheme and a second and different composition used for the rear contact layer corresponds to a second and different color code of the color code scheme.

8. The photovoltaic device of claim 1, wherein an anti-reflective coating (ARC) layer is deposited on the top surface of the one or more photovoltaic cells and on a top surface of the rear contact layer exposed by an isolation etching operation that forms the areas outside of the areas covered by the one or more photovoltaic cells.

9. The photovoltaic device of claim 1, wherein the color code scheme includes multiple color codes to correspond to multiple product configurations of the photovoltaic device, and wherein the multiple color codes in the color code scheme include one or more of red, purple, pink, or blue.

10. The photovoltaic device of claim 1, wherein the unique color code identifies a type of junction used in the one or more photovoltaic cells, an arrangement of the one or more photovoltaic cells, or both, and wherein the type of junction is one of a single junction, a dual junction, or a triple junction.

11. A method of forming a photovoltaic device that produces a unique color code in a color code scheme to identify a particular product configuration of the photovoltaic device, comprising:
forming one or more photovoltaic cells;
forming a rear contact layer on a rear surface of the one or more photovoltaic cells; and
forming a reflector on a rear surface of the rear contact layer,
wherein the one or more photovoltaic cells have a top surface on which light is to be incident, and
wherein the rear contact layer includes one or both of a composition or a thickness configured to produce the unique color code in the color code scheme that is visible in areas of the photovoltaic device outside of areas covered by the one or more photovoltaic cells and corresponding to the particular product configuration of the photovoltaic device.

12. The method of claim 11, wherein the composition of the rear contact layer includes a particular composition of compound semiconductor materials to produce the unique color code.

13. The method of claim 12, wherein the compound semiconductor materials include group III-V semiconductor materials.

14. The method of claim 11, further comprising:
performing an isolation etching operation to form the areas outside of the areas covered by the one or more photovoltaic cells and thereby expose a front surface of the rear contact layer to make the unique color code produced by the rear contact layer that is visible.

15. The method of claim 14, further comprising:
depositing an anti-reflective coating (ARC) layer on the top surface of the one or more photovoltaic cells and on a top surface of the rear contact layer exposed by the isolation etching operation that forms the areas outside of the areas covered by the one or more photovoltaic cells.

16. The method of claim 11, further comprising:
verifying that the unique color code corresponds to the particular product configuration of the photovoltaic device.

17. The method of claim 11, wherein the color code scheme includes multiple color codes to correspond to multiple product configurations of the photovoltaic device, and wherein the multiple color codes in the color code scheme include one or more of red, purple, pink, or blue.

18. The method of claim 11, wherein the unique color code identifies a type of j unction used in the one or more photovoltaic cells, an arrangement of the one or more photovoltaic cells, or both, and wherein the type of junction is one of a single junction, a dual junction, or a triple junction.

19. The method of claim 11, wherein a first thickness used for the rear contact layer corresponds to a first color code of the color code scheme and a second and different thickness used for the rear contact layer corresponds to a second and different color code of the color code scheme.

20. The method of claim 11, wherein a first composition used for the rear contact layer corresponds to a first color code of the color code scheme and a second and different composition used for the rear contact layer corresponds to a second and different color code of the color code scheme.
